(19) United States
(12) Patent Application Publication
(10) Pub. No.: US 2024/0363772 A1
(43) Pub. Date: Oct. 31, 2024

(54) APPARATUS AND METHOD FOR ABSORBING ELECTROMAGNETIC RADIATION, SYSTEM FOR USE IN AN IMAGE SENSOR, AS WELL AS A METHOD FOR MANUFACTURING AN APPARATUS FOR ABSORBING ELECTROMAGNETIC RADIATION

(71) Applicants: Fraunhofer-Gesellschaft zur Förderung der angewandten Forschung e.V., München (DE); Brandenburgische Technische Universität (BTU) Cottbus-Senftenberg, Körperschaft des öffentichen Rech, Cottbus (DE)

(72) Inventors: Lion AUGEL, Dresden (DE); Jens KNOBBE, Dresden (DE)

(21) Appl. No.: 18/679,626

(22) Filed: May 31, 2024

Related U.S. Application Data
(63) Continuation of application No. PCT/EP2022/083744, filed on Nov. 29, 2022.

(30) Foreign Application Priority Data
Dec. 2, 2021 (DE) 10 2021 213 747.4

(51) Int. Cl. H01L 31/0232; H01L 31/0352; H01L 31/108; H01L 31/18

(52) U.S. Cl. CPC H01L 31/02327; H01L 31/035281; H01L 31/1085; H01L 31/1804

(57) ABSTRACT

Embodiments according to the present invention include an apparatus for absorbing electromagnetic radiation, including a semiconductor substrate with a main side and a trench structure introduced into the main side and including at least one trench in the semiconductor substrate, wherein each trench of the trench structure comprises a trench floor area, and wherein the semiconductor substrate is transparent for the electromagnetic radiation. The apparatus further includes a metal material arranged in the trench floor area, wherein, together with the semiconductor substrate, the metal material provides a Schottky junction configured for absorbing the electromagnetic radiation, and a filling structure, which fills the trench and forms a common surface with the main side. Moreover, the apparatus includes a reflector arranged at the common surface and configured to at least partially reflect the electromagnetic radiation received by the semiconductor substrate in the direction of the metal material.

### CROSS-REFERENCES TO RELATED APPLICATIONS

This application is a continuation of copending International Application No. PCT/EP2022/083744, filed Nov. 29, 2022, which is incorporated herein by reference in its entirety, and additionally claims priority from German Application No. DE 10 2021 213 747.4, filed Dec. 2, 2021, which is incorporated herein by reference in its entirety.

Embodiments of the present invention include apparatuses and methods for absorbing electromagnetic radiation, systems for use in an image sensor, as well as methods for manufacturing apparatuses for absorbing electromagnetic radiation. The present invention further relates to photo detectors for electromagnetic radiation based on internal photoemission (IPE) with a plasmonic absorber.

Further embodiments according to the present invention include IPE photo detectors.

### BACKGROUND OF THE INVENTION

Among other things, problems that may be addressed with embodiments of the invention are described in the following.

Photodiodes may be used to detect electromagnetic radiation. The radiation is converted in the device into an electrically measurable photocurrent. In this case, the sensitivity of a photodiode depends, among other things, on the wavelength of the radiation to be detected. In addition to the type of the semiconductor material used, such as silicon or gallium arsenide (GaAs), the design determines the performance of a photodiode (e.g. pin diodes or Schottky-Diodes). However, all photodiodes have in common the excitation of electric charge carriers in the semiconductor, which can be measured as a photocurrent.

The wavelength range of electromagnetic radiation that can be detected by a photodiode is essentially determined by the semiconductor material. Silicon diodes can be used to detect radiation in the visible range and the immediately adjacent infrared range up to a boundary wavelength of approximately 1100 nm. Beyond that, germanium or standard indium gallium arsenide (InGaAs) is used as a detector material up to a boundary wavelength of 1700 nm. The wavelength range can be extended to up to 2500 nm with InGaAs alloys with a high proportion of indium.

The range between 1000 and 2500 nm is very important for various applications. The field of telecommunication uses wavelengths of around 1300 nm or 1550 nm. Absorption bands of some important molecules that are of great significance to spectral analytics are located in the so-called near infrared spectral range (NIR) between 1000 and 2500 nm. Important applications in this spectral range can also be found in the field of field monitoring with lasers.

As stated above, silicon cannot be used in a conventionally configured diode design due to its lack of sensitivity in NIR. The semiconductor material InGaAs used instead is an excellent physical-technical detector material with high sensitivity, but it also has significant disadvantages (cf. “prior art”).

In other words, electromagnetic radiation in the infrared range above a wavelength of 1.1 μm cannot be efficiently detected by silicon photodetectors that operate on the principle of fundamental absorption. Photodetectors for this wavelength range using compatible technology therefore use the principle of internal photoemission. In this case, incident radiation generates charge carriers at a metal-semiconductor junction. However, such detectors have disadvantages with respect to the generated dark currents, furthermore, the junction represents a mirror for the incident radiation in the planar design of the device. While the first characteristic is disadvantageous due to an increase of noise of such a device, the second characteristic reduces the signal strength in the device since the incident radiation is reflected and therefore not absorbed. The first characteristic is caused by imperfections along the metal-semiconductor junction and scales with the surface area, the second characteristic (reflections) can be reduced through appropriate structures. This results in an opposing dependency, since surfaces that disperse more strongly (rough surfaces) go along with an increased metalized surface area.

For more details, prior art photodiodes of different designs are described in the following.

Photodiodes of different designs are well known in the prior art, and the underlying mechanisms of converting electromagnetic radiation in electric charge carriers in a semiconductor are well understood. The following particularly describes known devices for detecting radiation with wavelengths of more than approximately 1000 nm, together with the particularities prevailing in this wavelength range. The prior art differentiates between three large groups of known device concepts.

The p-i-n diode, or pin diode in short, is the design that is used most often. This is a layer sequence of doped and undoped areas in the semiconductor. The letters indicate the type of doping, i.e. the type of the majority charge carriers in the corresponding layer, p stands for holes, n stands for electrons, i stands for intrinsic, i.e. without doping. The conversion of radiation into a measurable photocurrent takes place in such a diode by means of the so-called photo effect. In this case, a photon is absorbed in the semiconductor, in particular in the intrinsic layer, and an electron is excited out of the valence band into the conduction band. Together with the created hole in the valence band, a charge carrier pair that is separated in the internal electric field between the layers and that can be detected as a photocurrent is formed. This basic principle is used for the prevalent semiconductors silicon, germanium, and different alloys in the field of compound semiconductors of main groups III and V in the periodic table of elements, so-called III/V semiconductors. Sometimes alloys of main groups II and VI, so-called II/VI semiconductors, such as e.g. mercury cadmium telluride (HgCdTe) are used. In particular, InGaAs is an advantageous semiconductor material for NIR.

However, the above described functionality is only ensured up to a certain boundary wavelength of the radiation to be detected, or the relevant energy of the associated photons. For wavelengths above this boundary and energies below this boundary, no electrons may be excited in principle. Through this, the diode becomes insensitive in this wavelength range. In this case, the boundary energy is a characteristic of the semiconductor used (the so-called band gap between the valence band and the conduction band). For element semiconductors such as silicon, the band gap is specified, for compound semiconductors, it may be set within certain limits by changing the alloy proportions of the elements involved. For silicon, this limit is at approximately 1100 nm, for germanium it is at approximately 1700 nm.

Due to the above mentioned reasons, pin diodes covering the range of 1000 nm to 2500 nm can only be realized with compound semiconductors. The most important semiconductor in this range is InGaAs with different alloys of a varying indium proportion. InGaAs pin diodes are characterized by a high sensitivity and are commercially available in many different designs. The greatest disadvantage of this material system is the non-compatibility with respect to the silicon technology. This results in relatively high costs for manufacturing the semiconductor material itself and for the process technology for realizing the devices. Furthermore, only a hybrid integration is possible in connection with integrated circuits usually manufactured using silicon technology. This also has a negative effect on the cost structure. Through this, many possible applications, in particular in the imaging field with diode arrays, can currently not be addressed or developed in an economically sensible way.

A further disadvantage is the use of the heavy metal arsenic in the InGaAs alloys. Since matters of sustainability will play a major role in the future, silicon technology has clear advantages.

Photoresistors form the second group of photodetectors in NIR. These devices change their resistance when being irradiated with electromagnetic radiation. Based on this characteristic, a photocurrent can also be measured. These devices are not diodes and therefore do not precisely belong directly to the prior art, however, they form an important group of photodetectors in NIR. Lead selenide and lead sulphide are often used as a material. Different designs, e.g. individual elements and line arrays, of these photodetectors are also commercially available. The disadvantages of this technology are similar to that of III/V semiconductors. The technology is not compatible with the silicon technology and contains lead as a heavy metal. In addition, there are also technical disadvantages. Photoresistors are comparably slow and potentially degrade in case of unintentional irradiation with UV light. Through this, many possible applications, in particular in the imaging field with detector arrays, can currently not be addressed or developed in an economical sensible way.

The third group of photodetectors in NIR is formed by devices that are based on the mechanism of internal photoemission. At the interface between a semiconductor and a metal, a potential barrier may be formed (Schottky junction or Schottky barrier), depending on the material pairing. Electrically, such an interface acts like a diode in which the current flow across the interface takes place only for one polarity. Such devices are called Schottky diodes. If electromagnetic radiation is incident on the metal layer at the interface, an electron (or hole, depending on the doping of the semiconductor) may be released from the metal and may transition into the adjacent semiconductor. These charge carriers can then again be measured as a photocurrent, cf. FIG. 7. FIG. 7 shows a schematic view of a Schottky junction between a metal and a semiconductor in the band model. As shown in FIG. 7, e.g., the semiconductor may be n-doped or may be strongly n-doped (n⁺). Through the contact area of the semiconductor with the metal, there is a shift of the valence band (E_{V}) and the conduction band (E_{C}) in the semiconductor in the area of the junction. The Fermi energy is indicated with E_{F}. Through an incident photon having the energy hv, an electron e from the metal may overcome the potential barrier E_{B} and may contribute to a photocurrent. The remaining hole is indicated with h.

The conventional technology knows planar designs of Schottky diodes. FIG. 8 schematically shows a simplified Schottky diode using planar technology. On a silicon substrate 1, a metal layer 2 is deposited, with the Schottky junction (or Schottky barrier) being created at the interface between the metal layer 2 and the substrate 1. In addition to the metal layer 2, a (ohmic) contact 3 for electrically contacting the substrate 1 is deposited. The contact is illustrated in a simplified way. It may consist of several layers and implementation areas in the substrate. For example, the substrate 1 may be n-doped. The metal layer 2 is provided with an electrical contacting 2a, the ohmic contact 3 with the contacting 3a. In case of a corresponding polarity, a current may flow across the contactings 2a and 3a through the diode.

When being irradiated with electromagnetic radiation, the diode of FIG. 8 may possibly be used as a photodiode, as schematically illustrated in FIG. 9. Illumination takes place from the rear side of the device through the substrate since the radiation on the front side of the metal 2 would only be reflected and would therefore not reach the interface between the metal 2 and the semiconductor substrate 1. Since the diode is operated in a wavelength range above the boundary wavelength of the semiconductor, the semiconductor substrate 1 is transparent for this wavelength range. After transmission of the substrate 1, the radiation 6 is incident on the metal layer 2. There, for example, an electron 4 may be conveyed out of the metal 2 across the Schottky barrier into the substrate 1. If a sufficient number of charge carriers is “generated” in this way, they may be measured as a photocurrent 7 across the contactings 2a and 3a.

The greatest disadvantage of the above-described use of planar Schottky diodes as photodiodes is the very low sensitivity. Releasing charge carriers out of the metal 2 takes place only in a very thin interface of the metal since the charge carriers otherwise lose their energy by dispersion processes in the metal before reaching the Schottky barrier. In addition, the probability for release that goes along with an energetic excitation of the charge carriers in the metal 2 is generally low. The largest part of the radiation is reflected by the planar metal layer 2 acting as a mirror and is therefore lost. Thus, simple planar Schottky diodes have not found use as photodiodes.

In science, some approaches for increasing the sensitivity for Schottky photodiodes have been examined. On the one hand, the planar metal layer 2 may be integrated into an optical resonator. To this end, in the simplest case, a dielectric mirror layer tuned to a wavelength is deposited on the rear side of the substrate 1. Together with the metal layer 2, this results in a resonator that reduces the reflection losses of the metal layer due to multi-reflection in the resonator. Different designs of this principle have been examined [1]. However, the moderate improvement of the sensitivity achieved in this approach is significantly limited by two significant disadvantages. The Q factor of the optical resonator strongly depends on the wavelength of the radiation. Through this, the wavelength range for which the sensitivity can be increased is too small for many applications. Furthermore, there is a strong dependency on the angle of incidence of the radiation in such a design. This is also disadvantageous for many applications.

In other words, optimization methods that try to increase the efficiency of such device approaches by absorbing the incident radiation to a large part or even fully are known from science and practice. This may be realized by a structured surface within the detector [2, 4], the realization of layer stacks having optimized mirror properties [5, 6], or the use of plasmonic structures, with these also being used in combination with structured surfaces [7-9]. A special form of a plasmonic structure used for absorbing incident radiation is a so-called “plasmonic perfect absorber” [10]. In this case, plasmonically active structures are arranged in front of a continuous metallization such that there is an approximately full absorption of the incident radiation within the plasmonic structure for specific frequencies. This behavior is based on the excitation of nanostructures in their eigenfrequency. The prior art describes such structures only in the sense of the pure absorption of the incident radiation. Complete devices in connection with internal photoemission as a mechanism for generating a photocurrent are not described to date. The absorber structures known from the prior art convert the absorbed radiation into heat (energy conservation).

Further approaches from the prior art are known, e.g., from US2019/0378674 A1. US2019/0378674 A1 relates to an ultrathin highly efficient photoelectric apparatus using a plasmonic cavity with subwavelength hole-array (PlaCSH). US2003/0122210 A1 relates to a photo detector including a semiconductor substrate, a buried insulator formed on the substrate, a buried mirror formed on the buried insulator, a semiconductor-on-insulator (SOI) layer formed on the conductor, alternating n-doped p-type fingers formed in the semiconductor-on-insulator layer, and a rear contact with one of the doped p-type fingers and the doped n-type fingers.

It is the object of the present invention to provide a concept that enables an improved compromise between sensitivity and effectiveness of radiation absorption as well as between a component complexity and a manufacturing effort.

### SUMMARY

An embodiment may have an apparatus for absorbing electromagnetic radiation, the apparatus comprising: a semiconductor substrate with a main side and a trench structure introduced into the main side and comprising at least one trench in the semiconductor substrate, wherein each trench of the trench structure comprises a trench floor area, and wherein the semiconductor substrate is transparent for the electromagnetic radiation; and a metal material arranged in the trench floor area, wherein, together with the semiconductor substrate, the metal material provides a Schottky junction configured for absorbing the electromagnetic radiation; and a filling structure arranged in the trench and filling the trench and forming a common surface with the main side; and a reflector arranged at the common surface and configured to at least partially reflect the electromagnetic radiation received by the semiconductor substrate in the direction of the metal material.

Another embodiment may have a system for use in an image sensor, comprising: a multitude of apparatuses according to the invention, wherein the multitude of apparatuses is arranged in a grid or in a matrix, and wherein one or multiple apparatuses of the multitude of apparatuses are each assigned to each grid or matrix element, and wherein the system is configured to evaluate the one or multiple apparatuses of a grid or matrix element, each regarding a photocurrent created by absorption of electromagnetic radiation.

Another embodiment may have a method for absorbing electromagnetic radiation, comprising: irradiating a semiconductor substrate with the electromagnetic radiation, wherein the semiconductor substrate is irradiated from a rear side opposite a main side of the semiconductor substrate, and wherein the semiconductor substrate comprises a trench structure introduced into the main side of the semiconductor substrate and comprising at least one trench in the semiconductor substrate, wherein each trench of the trench structure comprises a trench floor area, and wherein the semiconductor substrate is transparent for the electromagnetic radiation, and wherein a metal material is arranged in the trench floor area, wherein, together with the semiconductor substrate, the metal material provides a Schottky junction configured for absorbing the electromagnetic radiation, and wherein a filling structure is arranged in the trench and filling the trench and forms, together with the main side, a common surface absorbing the electromagnetic radiation in the Schottky junction; and/or at least partially transmitting the electromagnetic radiation through the trench structure, and at least partially reflecting the electromagnetic radiation at a reflector arranged at the common surface and configured to reflect the electromagnetic radiation received by the semiconductor substrate in the direction of the metal material.

Another embodiment may have a method for manufacturing an apparatus for absorbing electromagnetic radiation, the method comprising: providing a semiconductor substrate with a main side, wherein the semiconductor substrate is transparent for the electromagnetic radiation; and introducing a trench structure into the main side of the semiconductor substrate and comprising at least one trench in the semiconductor substrate, and wherein each trench of the trench structure comprises a trench floor area; and arranging a metal material in the trench floor area, wherein, together with the semiconductor substrate, the metal material provides a Schottky junction configured for absorbing the electromagnetic radiation; and filling the trench with a filling structure, so that, together with the main side, the filling structure forms a common surface; and arranging a reflector at the common surface, wherein the reflector is configured to at least partially reflect the electromagnetic radiation received by the semiconductor substrate in the direction of the metal material.

Embodiments according to the present invention include an apparatus for absorbing electromagnetic radiation, the apparatus including a semiconductor substrate with a main side and a trench structure introduced into the main side and including at least one trench in the semiconductor substrate, wherein each trench of the trench structure comprises a trench floor area, and wherein the semiconductor substrate is transparent for the electromagnetic radiation. The apparatus further includes a metal material arranged in the trench floor area, wherein, together with the semiconductor, the metal material provides a Schottky junction configured for absorbing electromagnetic radiation, and forms a filling structure arranged in the trench, which fills the trench and forms a common surface with the main side. Moreover, the apparatus includes a reflector arranged on the common surface, the reflector being configured to at least partially reflect the electromagnetic radiation received by the semiconductor substrate in the direction of the metal material.

Embodiments according to the present invention are based on the core idea to improve absorption of electromagnetic radiation by means of synergy effects between a trench structure, which provides a Schottky junction for radiation absorption, and a reflector, which is arranged at the trench structure and on a filling structure of a trench of the trench structure.

The inventors have found that, by means of the trench structure, which may include a plurality of trenches, absorption of radiation at Schottky junctions in the area of the trench floors can be improved. Furthermore, due to the design of the trench structure and the metal material, plasmonic effects in the metal material can be used, which may lead to a further improvement of absorption. In other words, the metal material may be configured as a plasmonic structure.

According to the invention, a common surface can be created by filling the trench structure with the filling structure. Thus, e.g., a planar surface can be created. The filling structure itself may, in turn, include, e.g., a semiconductor material and, again, form Schottky junctions with the metal material. However, the fillings structure may also include an insulator. Due to the filling structure, stability and robustness of the apparatus can be ensured.

The reflector is arranged at the common surface and may improve the absorption behavior of the apparatus even further. Thus, radiation, which has not been directly absorbed in the Schottky junction on the trench floor after penetrating into the substrate, may be reflected back, by the reflector, in the direction of the metal material and, thus, in the direction of the Schottky junction, so that the absorption probability can be improved.

Due to the trench structure introduced in the semiconductor substrate and the subsequent filling of the trenches, a corresponding apparatus can be manufactured with low effort by means of established manufacturing methods and, thus, in great quantities.

Thus, an apparatus can be provided, which enables an improved compromise between sensitivity and effectiveness of radiation absorption, as well as a component complexity and a manufacturing effort.

According to further embodiments of the present invention, the trench structure comprises a plurality of trenches, and the metal material is arranged, in each case, in the trench floor areas of the plurality of trenches. In this regard, the trench structure, together with the metal material arranged, in each case, in the trench floor areas of the plurality of trenches, forms a lattice structure, and the lattice structure is further configured to at least partially transmit electromagnetic radiation in a predetermined wavelength range and to at least partially reflect electromagnetic radiation outside of the predetermined wavelength range. In other words, the lattice structure may form an optical filter in order to absorb, e.g., light having certain properties. Thus, the lattice structure offers a wider degree of freedom for setting the sensitivity of the apparatus.

According to further embodiments of the present invention, the lattice structure comprises a lattice constant, and the lattice constant is determined by the distance of the metal material of two adjacent trenches of the trench structure. The lattice constant further amounts to at least 100 nm and at most 1000 nm, or the lattice constant amounts to at least 100 nm and at most 4000 nm.

According to further embodiments of the present invention, the lattice structure is configured to transmit the electromagnetic radiation in dependence on the polarization of the electromagnetic radiation. Thus, a polarization-dependent apparatus may be created, so that light is absorbed or reflected away depending on the polarization.

According to further embodiments of the present invention, the lattice structure is a one-dimensional lattice structure and causes a transmission of the electromagnetic radiation in dependence on the polarization of the electromagnetic radiation. A one-dimensional lattice may be, e.g., a lattice that is describable by a single lattice parameter, e.g., the distance from adjacent, e.g., parallel, lattice elements. Thus, worded differently, the apparatus is polarization-sensitive, so that, in this way, e.g., polarization properties of the absorbed radiation may also be determined.

According to further embodiments of the present invention, the trenches of the trench structure comprise, in a plane parallel to the main side of the semiconductor substrate, a first extension and a second extension approximately perpendicular to the first extension, wherein the first extension is greater than the second extension, and wherein the trenches of the trench structure are arranged in parallel to one another on the main side of the semiconductor substrate, with an approximately equal distance in each instance. Simply put, the trenches may be arranged in parallel to one another in the form of strips. Such a structure may, e.g., be easy to produce and comprise a polarization sensitivity.

According to further embodiments of the present invention, the lattice structure is configured to transmit the electromagnetic radiation with a first polarization direction and a second polarization direction. The apparatus may thus be, e.g., insensitive towards the two polarization directions, so that, e.g., no, or only minor, polarization-dependent absorption losses occur, so that a photocurrent provided by the radiation absorption may comprise a high amount, or, in other words, a large part of the incident radiation may contribute to a photocurrent.

According to further embodiments of the present invention, the lattice structure is a two-dimensional lattice structure and causes a transmission of the electromagnetic radiation with the first polarization direction and the second polarization direction. A two-dimensional lattice structure may be describable, e.g., by two lattice vectors. The lattice structure may be described, e.g., by two lengths and the angle between the lattice vectors.

According to further embodiments of the present invention, the trenches of the trench structure are formed as holes, and the holes are arranged with a predetermined distance from one another in a regular arrangement. The configuration as a trench structure with holes, or worded differently, perforated lattices, may be produced, e.g., with little time and technological effort. The holes may be created, e.g., by etching methods common in semiconductor technology.

According to further embodiments of the present invention, the apparatus includes a plurality of different lattice structures. Optionally, the different lattice structures may be arranged irregularly and/or be distributed randomly.

According to further embodiments of the present invention, the metal material arranged in the trench floor area is configured to facilitate the absorption of the electromagnetic radiation at the Schottky junction by means of plasmonic effects. For example, due to the dimensioning of the metal material, the plasmonic effects may occur in the area of the Schottky junctions and thus increase the absorption efficiency.

According to further embodiments of the present invention, the Schottky junction is adapted to a wavelength range, and the metal material is dimensioned, in dependence on said wavelength range, such that, upon irradiation of the apparatus with electromagnetic radiation having wavelengths within the wavelength range, plasmonic effects occur or are amplified, in order to facilitate the absorption of the electromagnetic radiation at the Schottky junction by means of the plasmonic effects. Alternatively or additionally, the metal material is composed, in dependence on the wavelength rage, such that, upon irradiation of the apparatus with electromagnetic radiation having wavelengths within the wavelength range, the absorption is facilitated by the composition of the metal material.

Thus, the apparatus may be configured, e.g., in an application-specific manner for a particular spectral range to be detected. The selectivity of the absorption may accordingly be achieved, e.g., by a design of the apparatus, which allows for the efficient absorption by means of plasmonic effects only in the desired wavelength range. Alternatively or additionally, this effect may also be achieved by a material selection of the metal material adapted to the wavelength range. Thus, a wavelength-sensitive apparatus can be provided.

According to further embodiments of the present invention, the metal material is configured to form, together with the reflector, a resonator for the electromagnetic radiation. An absorption probability of the radiation may be, e.g., increased significantly, for example, by reflection and multi-reflection between the reflector and the metal material.

According to further embodiments of the present invention, the apparatus is configured to absorb the electromagnetic radiation based on an internal photoemission and using the Schottky junction, wherein the absorption of the electromagnetic radiation is facilitated by plasmonic effects in the metal material and by multi-reflection between the reflector and the metal material. The synergetic utilization of the advantages of the trench structure, resonator and of plasmonic effects allows for a high absorption efficiency.

According to further embodiments of the present invention, the apparatus includes a first and a second electrical contacting, and the first contacting is connected to the metal material so as to be electrically conductive and the second contacting is connected to the semiconductor substrate so as to be electrically conductive. Furthermore the first and second contacting are configured to provide a photocurrent on the basis of an internal photoemission through electromagnetic radiation absorbed at the Schottky junction. The photocurrent may be used, e.g., for further signal evaluations.

According to further embodiments of the present invention, the first and second contacting are arranged at opposite sides of the apparatus, or the first and second contacting are arranged on the same side of the apparatus. In other words, embodiments according to the present invention include apparatuses with front-side contacting or with rear-side contacting. Embodiments are not limited to a specific form of contacting. Depending on a further integration with further elements, an advantageous design may be selected so that a good compromise may be achieved between the efforts for manufacturing and integration.

According to further embodiments of the present invention, the apparatus is configured to absorb electromagnetic radiation having a wavelength of at least 1 μm and at most 12 μm, or of at least 1 μm and at most 3 μm. Due to the inventive advantage of an efficient absorption, e.g., materials may be used for the above-mentioned wavelength ranges that comprise good properties regarding manufacturing, but would actually not be suitable for this wavelength range when using prior art techniques, e.g., silicon for near infrared radiation.

According to further embodiments of the present invention, the semiconductor substrate comprises a doping, and a doping degree of the doping towards the Schottky junction is constant, stepped, or gradually variable. Thus, the properties of the semiconductor in the area of the Schottky junction can be set precisely, so that an application-specific combination of material and geometry comprises good absorption properties and, e.g., also contacting properties.

According to further embodiments of the present invention, the semiconductor substrate includes a layer stack and/or the semiconductor substrate includes silicon, germanium and/or a metal material compound including silicon and/or germanium.

Alternatively or additionally, the metal material includes a layer stack and/or the metal material includes a metal, a silicide, and/or a metallic nitride. Alternatively or additionally, the filling material includes a semiconductor material and/or an insulator material. According to embodiments of the present invention, silicone technology, which is cost-efficient and widely available, may be used to manufacture inventive apparatuses. In this case, e.g., due to the absorption efficiency improved according to invention, silicon may also be used in wavelength ranges (e.g. NIR) for which silicone has insufficient radiation absorption in conventional approaches.

According to further embodiments of the present invention, the metal material includes at least one of aluminum, copper, nickel, gold, titanium, nickel silicide, cobalt silicide, titanium silicide, and/or titanium nitride. Embodiments according to the present invention enable the use of a multitude of metal materials, e.g., so that an advantageous material combination of the beam guiding unit and the metal material, e.g. a metallization, may be used depending on the radiation to be detected.

According to further embodiments of the present invention, the filling material includes Poly-Si, SiO₂, and/or SiN.

According to further embodiments of the present invention, the trench structure comprises an extension vertical to the main side of the semiconductor substrate, which amounts to at least 50 nm and at most 1000 nm, or to at least 80 nm and at most 1200 nm, or to at least 50 nm and at most 4000 nm.

Further embodiments of the present invention include a system for use in an image sensor, the system including a multitude of apparatuses according to one of the preceding claims, wherein the multitude of apparatuses is arranged in a grid or in a matrix, and wherein one or more apparatuses of the multitude of apparatuses are each assigned to a grid or matrix element. Furthermore, the system is configured to evaluate the one or multiple apparatuses of a grid or matrix element, each regarding a photocurrent created by absorption of electromagnetic radiation. According to the invention, detectors may therefore be built out of a multitude of previously described apparatuses that are able to absorb and detect, e.g., even very little amounts of incident radiation. Through an individual evaluation, e.g., there may be a localization of radiation in the Schottky junctions of the individual apparatuses or matrix or grid elements.

Further embodiments including methods according to the present invention will be described in the following. Inventive methods are based on the same or similar considerations and ideas as inventive apparatuses so that inventive methods may have corresponding features, functionalities, and advantages of apparatuses, individually or in combination. Vice versa, inventive apparatuses may also have corresponding features, functionalities, and advantages of methods, individually or in combination.

Further embodiments according to the present invention include a method for absorbing electromagnetic radiation, the method including irradiating a semiconductor with the electromagnetic radiation, wherein the semiconductor substrate is irradiated by a rear side opposite a main side of the semiconductor substrate, and wherein the semiconductor substrate comprises a trench structure introduced into the main side of the semiconductor substrate and including at least one trench in the semiconductor substrate, each trench of the trench structure comprising a trench floor area. Furthermore, the semiconductor substrate is transparent for the electromagnetic radiation, and a metal material is arranged in the trench floor area, wherein, together with the semiconductor substrate, the metal material provides a Schottky junction configured for absorbing the electromagnetic radiation. Moreover, a filling structure is arranged in the trench, which fills the trench forms a common surface together with the main side. The method further includes absorbing the electromagnetic radiation in the Schottky junction; and/or at least partially transmitting the electromagnetic radiation through the trench structure, and at least partially reflecting the electromagnetic radiation at a reflector arranged at the common surface and configured to reflect the electromagnetic radiation received by the semiconductor substrate in the direction of the metal material.

Further embodiments according to the present invention include a method for manufacturing of an apparatus for absorbing electromagnetic radiation, the method including providing a semiconductor substrate with a main side, wherein the semiconductor substrate is transparent for the electromagnetic radiation; and introducing a trench structure into the main side of the semiconductor substrate, wherein the trench structure includes at least one trench, and wherein each trench of the trench structure comprises a trench floor area. The method further includes arranging a metal material in the trench floor area, the metal material, together with the semiconductor substrate, providing a Schottky junction configured for absorbing the electromagnetic radiation, and filling the trench with a filling structure, so that the filling structure forms a common surface together with the main side. Furthermore, the method includes arranged a reflector on the common surface, the reflector being configured to at least partially reflect the electromagnetic radiation received by the semiconductor substrate in the direction of the metal material.

### BRIEF DESCRIPTION OF THE DRAWINGS

Embodiments of the present invention will be detailed subsequently referring to the appended drawings, in which:

FIG. 1 shows a schematic side view of an apparatus for absorbing electromagnetic radiation according to an embodiment of the present invention;

FIG. 2 shows a schematic side view of an apparatus for absorbing electromagnetic radiation with a multitude of trenches, according to embodiments of the present invention;

FIG. 3a) shows an example of a polarization-sensitive lattice structure;

FIG. 3b) shows an example of a lattice structure that is not sensitive to polarization;

FIG. 4 shows a schematic side view of an apparatus for absorbing electromagnetic radiation with optional contactings, according to embodiments of the present invention;

FIG. 5 shows a system for use in an image sensor according to embodiments of the present invention;

FIG. 6 shows a method for absorbing electromagnetic radiation according to embodiments of the present invention;

FIG. 7 shows a method for manufacturing an apparatus for absorbing electromagnetic radiation according to embodiments of the present invention;

FIG. 8 shows a schematic side view of a simplified Schottky diode using planar technology;

FIG. 9 shows a schematic side view of the Schottky diode of FIG. 7 when being irradiated; and

FIG. 10 shows a schematic view of a Schottky junction between a metal and a semiconductor in the band model.

### DETAILED DESCRIPTION OF THE INVENTION

Before embodiments of the present invention are subsequently described in detail on the basis of the drawings, it is to be noted that identical and functionally identical elements, objects, and/or structures or elements, objects, and/or structures having the same effect are provided with the same or similar reference numerals in the different drawings so that the description of these elements illustrated in different embodiments is interchangeable or can be applied to one another.

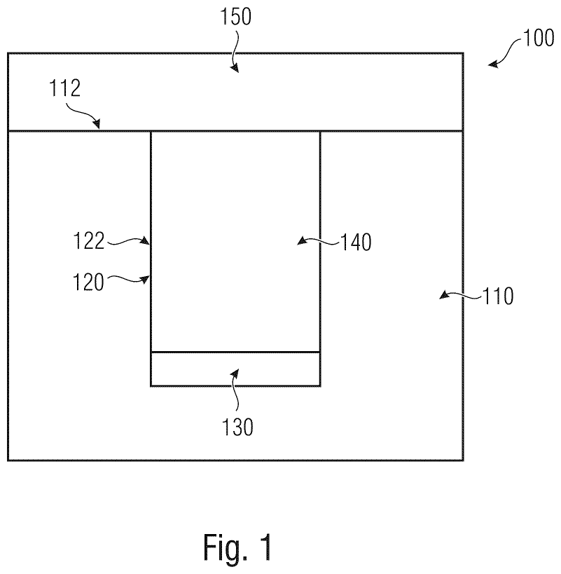

FIG. 1 shows a schematic side view of an apparatus for absorbing electromagnetic radiation according to embodiments of the present invention. Fig. shows the apparatus 100 with a semiconductor substrate 110, wherein the semiconductor substrate comprises a main side 112. A trench structure 120 is introduced into the main side 112. As an example, the trench structure 120 includes a trench 122. However, the trench structure 120 may also include a plurality of trenches.

At the trench floor areas of the trench, a metal material 130 is arranged, and the trench 122 is filled with a filling structure 140, so that, together with the semiconductor substrate, the filling structure 140 forms a common surface at the main side 112 of the semiconductor substrate 110. The common surface may, e.g., also be planar. However, the common surface may not be completely or actually planar, i.e., due to the process used, it may also deviate from a completely planar design. A reflector 150 is arranged on the common surface.

Electromagnetic radiation may, e.g., penetrate into the semiconductor substrate 110 from the side of the semiconductor substrate opposite the main side 122 (simply put, in FIG. 1, from below). In order to make this possible, the semiconductor substrate 110 is at least approximately transparent for the electromagnetic radiation, or, in other words, the semiconductor substrate 110 is configured to transmit a large portion (e.g., 90% or 95% or 99%) of electromagnetic radiation in a specific wavelength range. Subsequently, the radiation can be absorbed in a Schottky junction, which is formed between the metal material 130 and the semiconductor substrate 110. Non-absorbed radiation may be transmitted further to the reflector 150, where it may be reflected back in the direction of the metal material 130. Accordingly, again, an electron from the metal material 130 may be raised above the potential barrier of the Schottky junction due to the radiation, or simply put, the radiation may be absorbed. Starting from the metal material 130, the radiation may also be reflected back to the reflector 150, if it was not absorbed, wherein the radiation may, in turn, be reflected again from there in the direction of the metal material 130. In summary, the metal material 130 and the reflector may therefore form a resonator for the electromagnetic radiation. Thus, an absorption probability of the radiation may be increased.

Generally, an improvement of the absorption probability based on plasmonic effects in the metal material 130 and based on multi-reflections between the reflector 150 and the metal material 130 may be achieved according to embodiments. The absorption itself may take place on the basis of an internal photoemission using the Schottky junction.

Furthermore, the semiconductor substrate 110 may comprise a doping, wherein a doping degree of the doping towards the Schottky junction is constant, stepped, or gradually variable. Thereby, the properties of the semiconductor at the Schottky junction can be set precisely.

According to the invention, a corresponding doping course may relate to realized silicon ridges, i.e., a doping, e.g., an inventive doping course is usefully applicable from the plane of the “metal ridges”, e.g., the metal material 130, to the plane of the rear side reflector.

The semiconductor substrate 110 may, e.g., also be configured as a layer stack and/or include at least one of silicon, germanium and/or a metal material compound including silicon and/or germanium. Accordingly, the metal material 130, as well, may be configured as a layer stack and include at least one of a metal, a silicide, and/or a metallic nitride. Specifically, the metal material may include, e.g., at least one of aluminum, copper, nickel, gold, titanium, nickel silicide, cobalt silicide, titanium silicide, and/or titanium nitride. The filling material 140 may, again, include a semiconductor material and/or an insulator material. For example, the filling material 140 may include Poly-Si, SiO₂, and/or SiN.

A vertical extension of the trench structure 120, e.g., vertical to the main side 112 of the semiconductor substrate 110, may amount to at least 50 nm and at most 1000 nm, or to at least 80 nm and at most 1200 nm, or to at least 50 nm and at most 4000 nm.

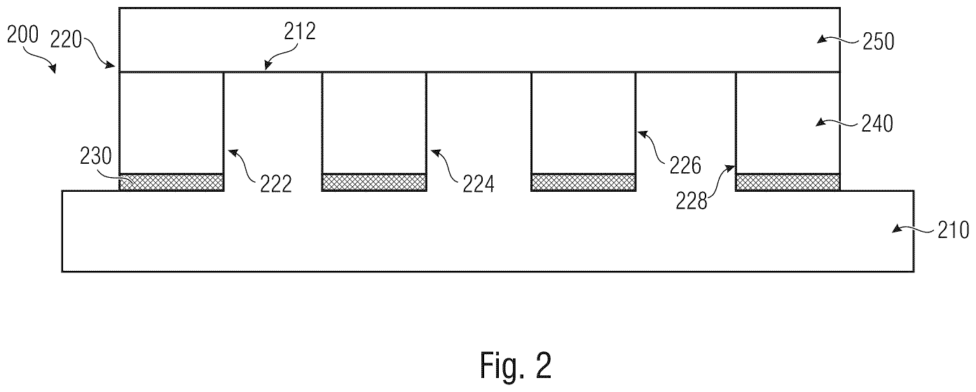

FIG. 2 shows a schematic side view of an apparatus for absorbing electromagnetic radiation with a multitude of trenches, according to embodiments of the present invention. FIG. 2 shows the apparatus including a semiconductor substrate 210 with the main side 212, in which the trench structure 220 is introduced.

As shown in FIG. 2 as an optional feature, the trench structure 220 may comprise multiple trenches 222, 224, 226, 228, or generally speaking, a multitude of trenches, which are filled with a filling structure 240. Furthermore, the apparatus 200 comprises a reflector 250 as discussed according to FIG. 1. A cross-section of one or multiple trenches of the trench structure may, in this case, be regularly or irregularly polygonal or elliptical, in particular round, wherein mixed forms thereof are possible, such as a polygon with rounded corners. Moreover, the trenches of the trench structure may also be connected to one another, so that, e.g., columns are formed by the semiconductor substrate in the area of the trench structure. Accordingly, the metal material 230 as a metal material surface, which covers, e.g., the floor area that is a common floor area of the trench structure. In this case, the metal material 230 is arranged in each of the trench floor areas of the trenches 222, 224, 226, 228. The metal material 130 may, in this case, form a lattice structure together with the semiconductor material of the trench structure. The lattice structure may form an optical filter, so that electromagnetic radiation is at least partially transmitted or at least partially reflected in dependence on properties of the radiation. The lattice structure may, e.g., be tuned to a wavelength range, for which radiation is transmitted. Radiation with wavelengths outside of this range may consequently be, e.g., reflected and therefore not absorbed.

Generally, it should be noted that an ideal component may detect, e.g., all wavelengths, or electromagnetic waves, optimally without dependency. The effects from transmission and reflection may, e.g., be based on resonance effects, which, under some circumstances, may improve the generation of a photocurrent.

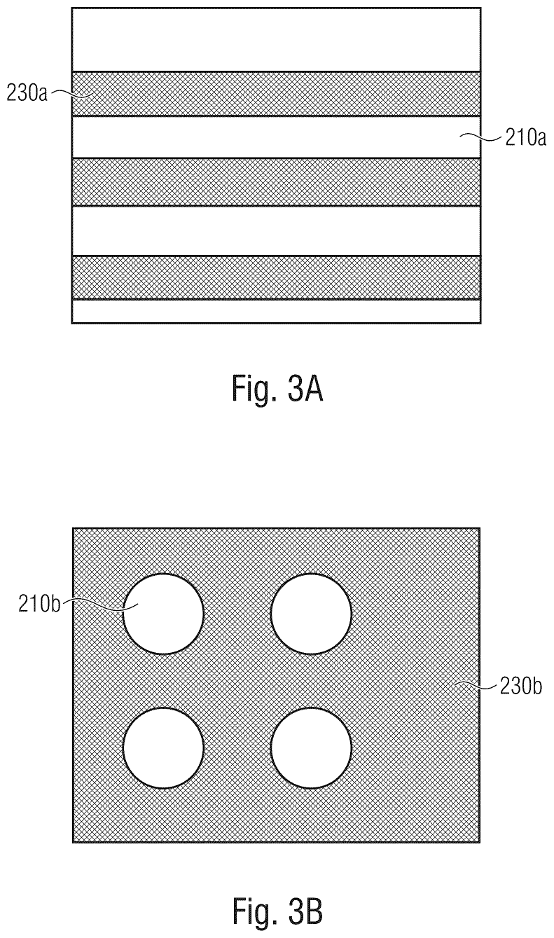

FIG. 3 shows schematic top views of lattice structures according to embodiments of the present invention. FIG. 3a) shows an example of a polarization-sensitive lattice structure. The top view of the lattice structure of FIG. 3a) shows a possible configuration of the apparatus 200 of FIG. 2. Accordingly, the metal material is denoted as 230a, the semiconductor substrate of the trench structure as 210a. In this configuration, electromagnetic radiation may be transmitted into the semiconductor or reflected away therefrom depending on the polarization of the radiation. For this purpose, the lattice structure is configured as a one-dimensional lattice, wherein the trenches comprise one long and one short axis here as an example, or in other words, they comprise a first extension and, approximately perpendicular to the first extension, a second extension, wherein the first extension is greater than the second extension. The trenches are arranged in parallel to one another according to their long axes, with an at least approximately equal distance. This distance may, e.g., form the lattice constant of the lattice.

Compared to this, FIG. 3b) shows an example of a lattice structure that is not sensitive to polarization. The top view of the lattice structure of FIG. 3b) shows a second possible configuration of the apparatus 200 of FIG. 2. The metal material is accordingly denoted as 230b, the semiconductor of the trench structure as 210b. In this configuration, electromagnetic radiation may be transmitted into the semiconductor independently of the first and second polarization directions of the radiation. For this purpose, the lattice structure is configured as a two-dimensional lattice structure. As an optional feature, the trenches of the trench structure are connected to one another and formed as a trench surface. In the area of the trench structure, the semiconductor substrate comprises columns 210b, the columns being arranged spaced apart at a predetermined regular distance from one another. This distance may form, e.g., a lattice constant of the lattice structure. The metal material 230b may be configured, e.g., so as to be planar, in order to achieve a continuous electrical contacting of this layer 230b. A contacting can therefore be provided, e.g., with low effort. Furthermore, the columns may comprise any shape of their footprint. I.e., the columns may comprise, e.g., a round, elliptical, or polygonal footprint.

Such an insensitivity to polarization may refer to, e.g., especially the linear polarization. In particular, normal ambient or illumination light may be unpolarized, in the sense that all linear polarization directions being superimposed on each other and therefore, polarization effects statistically disappear. The stripe lattice structure, e.g., of FIG. 3a) may, in this sense, have an, e.g., filtering effect for a preferential direction.

Accordingly, a random distribution may have, e.g., no two polarization directions.

Furthermore, it is to be noted that a completely polarization-free structure cannot be realized. I.e., a slight influence of the polarization axis on the absorption behavior may remain visible. For example, circularly polarized radiation may be represented as a superposition of the polarization axes of the realized structure, wherein the “portions” of the of the superposition vary in time. In an application, this means that a temporal variation of the generated photocurrent may occur.

In this case, it is pointed out that apparatuses according to embodiments may also comprise trench structures with different lattice structures. For example, apparatuses may thus comprise areas having lattice structures as shown in FIG. 3a) and areas having lattice structures as shown in FIG. 3b). These areas may be arranged, e.g., irregularly, and/or may be distributed randomly. The trenches also may comprise a multitude of possible shapes and designs, as seen in FIG. 3. In simple terms, the trenches may be configured as “elongate depressions”, as shown, e.g., in FIG. 3a), wherein the holes or hole structures are also to be understood as trenches. Accordingly, the trenches may also be configured as depressions with an oval, square, or other footprint.

Independently of the specific design of the lattice structure 220, the lattice constant may be determined by the distance of the metal material 230 of two adjacent trenches, e.g., in the shape of holes as shown in FIG. 2b). The lattice constant may amount to at least 100 nm and at most 1000 nm, or the lattice constant amounts to at least 100 nm and at most 4000 nm.

With reference to FIG. 2, the metal material 230 in the trench floor area may, e.g., be dimensioned such that plasmonic effects favor absorption of the electromagnetic radiation at the Schottky junction.

In this case, the plasmonic effects may occur, e.g., in dependence on the wavelength of incident electromagnetic radiation and/or in dependence on the material selection of the metal material 230.

According to embodiments in which the Schottky junction is adapted to a wavelength range, the metal material 230 may accordingly be dimensioned, in dependence on said wavelength range, such that, upon irradiation of the apparatus 200 with electromagnetic radiation having wavelengths within the wavelength range, plasmonic effects occur or are amplified, in order to facilitate the absorption of the electromagnetic radiation at the Schottky junction by means of the plasmonic effects, in order to facilitate the absorption of the electromagnetic radiation at the Schottky junction by means of the plasmonic effects.

Alternatively or additionally, the material of the metal material 230 may be selected such that, upon irradiation of the apparatus with electromagnetic radiation having wavelengths within the wavelength range, the absorption is facilitated by the material selection of the metal material.

A possible wavelength range to which the Schottky junction may be tuned, may include, e.g., wavelengths of at least 1 μm and at most 12 μm, or of at least 1 μm and at most 3 μm.

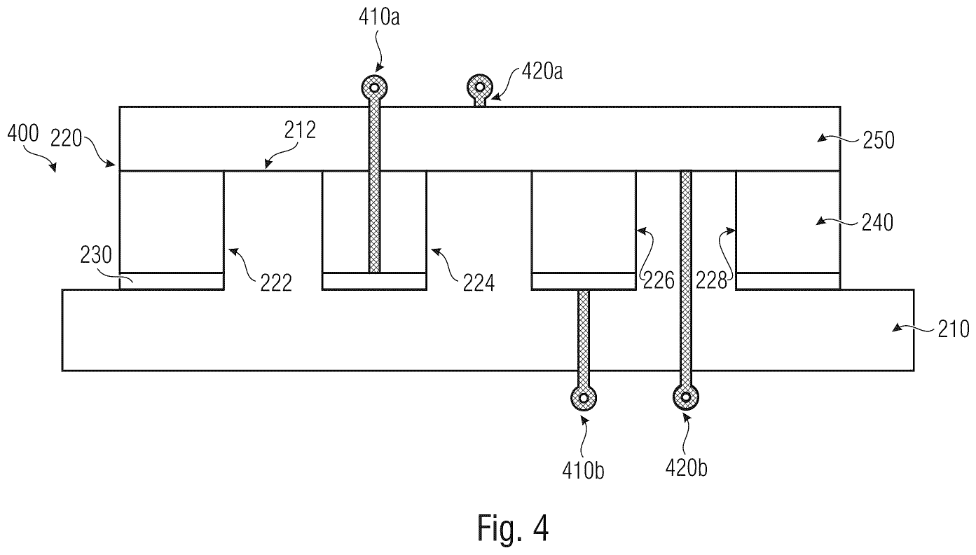

FIG. 4 shows a schematic side view of an apparatus for absorbing electromagnetic radiation with optional contactings, according to embodiments of the present invention. FIG. 4 shows the apparatus 400, which comprises further contactings in addition to the features discussed in the context of FIG. 2. The metal material 230 may, e.g., be contacted by a first contacting 410a from the side of the reflector 250 and through the filling structure 240, or also, e.g., by an alternative first contacting 410b from the opposite side and through the semiconductor substrate 210. Optional second contactings form the contactings 420a and 420b for contacting the semiconductor substrate 210. The reflector 250 may, in this case, serve, e.g., in the final apparatus, as a contacting of the opposite side of the Schottky diode. In other words, e.g., a contacting of the semiconductor substrate 210 may take place by means of the contacting 420a via the reflector 250. For this purpose, the reflector may be configured so as to be electrically conductive. Likewise, the contacting may take place, as shown, by means of the contacting 420b from a rear side of the apparatus. Here, as well, the reflector 250 may again be used as a contacting for the semiconductor substrate 210. FIG. 4 shows possible first and second contactings, which may be configured in any combination, in order to provide a photocurrent on the basis of an internal photoemission by means of electromagnetic radiation absorbed at the Schottky junction.

Thus, an apparatus may, e.g., have only the contactings 410a and 520b, so that the contactings are arranged at opposing sides. A further combination would be, e.g., the contacting 410b as the first contacting of the metal material 230 and the contacting 420b as the second contacting of the semiconductor substrate 210. Accordingly, the first and second contactings may be arranged on a same side of the apparatus. Accordingly, embodiments according to the present invention include both configurations with front and rear side contactings (or also, e.g., contactings on both sides). Here, it should also be noted that, e.g., for contacting the metal material, one contacting may suffice, e.g., when the metal material of the trench floors is connected, as shown in FIG. 3b). However, this is also possible with trench shapes as shown in FIG. 3a), e.g., with an additional connecting metallization or a corresponding connecting metal material, which connects the metal material of the trenches in an electrically conductive manner.

A possible ideal or idealized connection to the semiconductor 210 or the contacting could be configured, e.g., such that the contacting 420a reaches through the reflector 250 to the semiconductor 210, in order to contact the same. Accordingly, the contacting 420b could also contact, from the rear side, only the semiconductor substrate 210, without reaching up to the reflector 250.

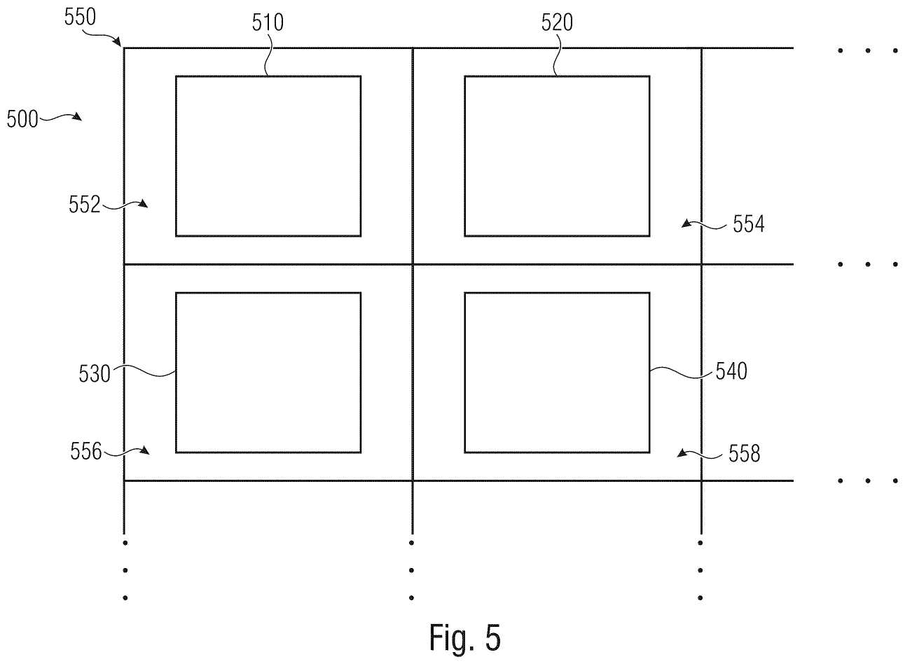

FIG. 5 shows a system for use in an image sensor according to embodiments of the present invention. The system 500 comprises a multitude of inventive apparatuses 510, 520, 530, 540, which are arranged in a matrix 550. Each apparatus is assigned to one matrix element 552, 554, 556, 558 (e.g., apparatus 510 to matrix element 552). However, it should be noted here that it is also possible for multiple apparatuses to be assigned to one matrix element. When electromagnetic radiation is incident on the system 500, it may be absorbed by one or multiple apparatuses, e.g., in dependence on the location of incidence of the radiation. By means of a complex evaluation of the individual matrix elements, this location may thus be determined. In other words, the system 500 may be configured to individually evaluate the one or multiple apparatuses of a matrix element, in each case regarding a photocurrent generated by absorbing electromagnetic radiation. According to the invention, the matrix 550 may also be replaced, for example, by a grid. In particular, the matrix 550 or the grid may comprise a random geometric arrangement of the partial elements 552, 554, 556, 558, i.e., for example, not a spatially even square distribution of the partial elements as shown in FIG. 5.

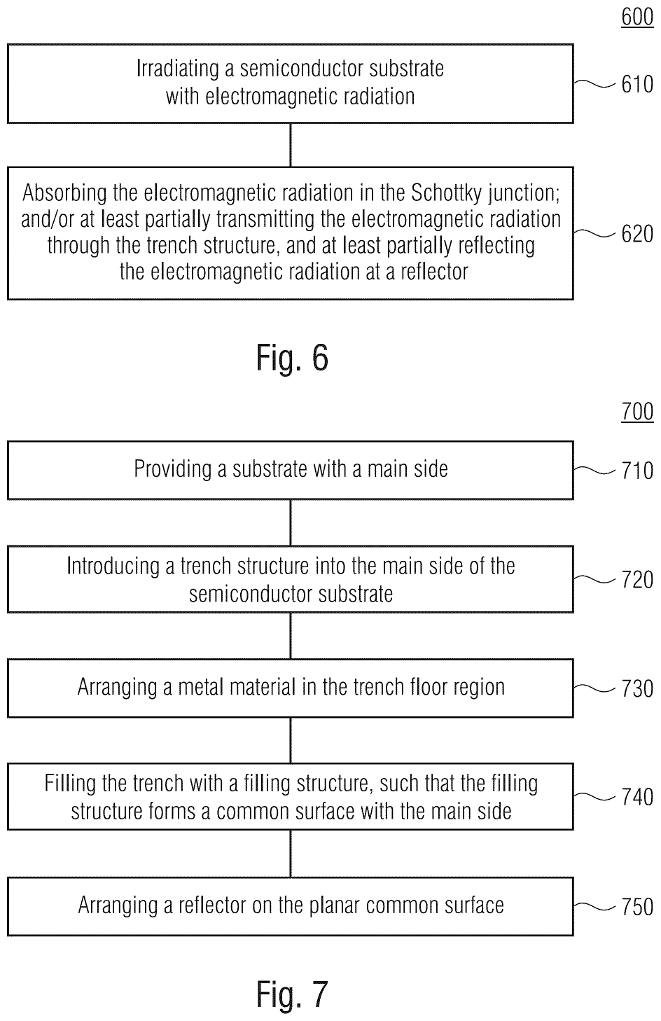

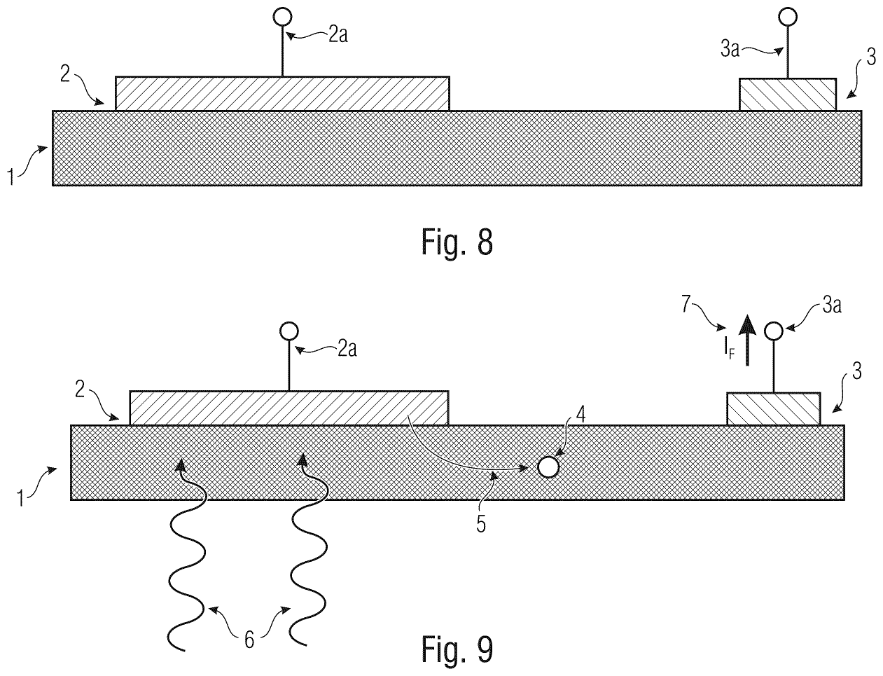

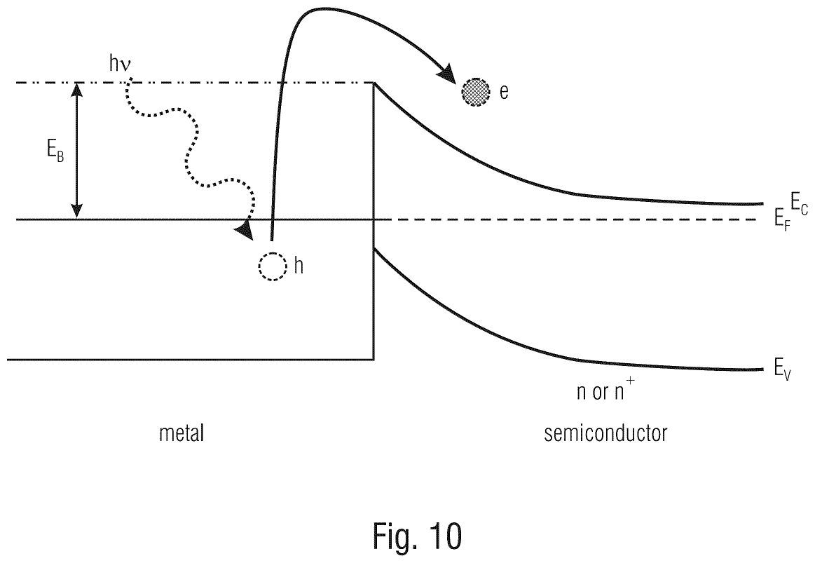

FIG. 6 shows a method for absorbing electromagnetic radiation according to embodiments of the present invention. The method 600 includes irradiating 610 a semiconductor substrate with the electromagnetic radiation, wherein the semiconductor substrate is irradiated from a rear side opposite a main side of the semiconductor substrate, and wherein the semiconductor substrate comprises a trench structure introduced into the main side of the semiconductor substrate and including at least one trench in the semiconductor substrate, wherein each trench of the trench structure comprises a trench floor area, and wherein the semiconductor substrate is transparent for the electromagnetic radiation. In this case, a metal material is arranged in the trench floor area, wherein, together with the semiconductor substrate, the metal material provides a Schottky junction configured for absorbing the electromagnetic radiation, and wherein a filling structure is arranged in the trench, which fills the trench and which, together with the main side, forms a common, e.g., planar, surface. The method further includes absorbing 620 the electromagnetic radiation in the Schottky junction and/or at least partially transmitting 620 the electromagnetic radiation through the trench structure, and at least partially reflecting 620 the electromagnetic radiation at a reflector arranged at the planar common surface, which reflector is configured to reflect the electromagnetic radiation received by the semiconductor substrate in the direction of the metal material.

FIG. 7 shows a method for manufacturing an apparatus for absorbing electromagnetic radiation according to embodiments of the present invention, including: providing 710 a semiconductor substrate with a main side, wherein the semiconductor substrate is transparent for the electromagnetic radiation, and introducing 720 a trench structure into the main side of the semiconductor substrate, wherein the trench structure includes at least one trench in the semiconductor substrate, and wherein each trench of the trench structure comprises a trench floor area. The method further includes arranging 730 a metal material in the trench floor area, wherein, together with the semiconductor substrate, the metal material provides a Schottky junction configured for absorbing the electromagnetic radiation, and filling 740 the trench with a filling structure, so that, together with the main side, the filling structure forms a common surface, as well as arranging 750 a reflector at the planar common surface, wherein the reflector is configured to at least partially reflect the electromagnetic radiation received by the semiconductor substrate in the direction of the metal material.

In the following, further embodiments are described, and some previously described embodiments are explained in other words. To this end, inventive ideas or ideas for solution of the invention according to embodiments are described in different words.

Embodiments according to the present invention are based on the finding that, on the one hand, silicon photodiodes (Schottky diodes) for near infrared radiation may be realized using the principle of internal photoemission, but in a planar design, these are often not sensitive enough for common applications. On the other hand, there are proposals for realizing a drastic increase of the optical absorption in metallic nanostructures on the basis of plasmonic effects, which, however, lack concepts for an electrical contacting and, generally, for generating a photocurrent. Thus, no solutions are known from the prior art, which allow realizing efficient IPE-based photodiodes.

A basic, inventive innovation relative to the prior art is using an internal photoemission as a mechanism for generating a photocurrent in connection with highly efficient plasmonic nanostructures. The realization of an electrical contacting of the nanostructures prior to the continuous metallization of the “perfect absorber”, which has not yet been described in the literature (FIG. 2), may come to be greatly significant. The realization may accordingly provide a structure with rear side illumination, wherein the plasmonic nanostructures facing the radiation may be buried in a structured silicon layer, i.e., for example, the trench structure. The nanophotonic cavity of the “perfect absorber” may also be filled with silicon, or, e.g., generally the filling structure. The escape of the charge carriers generated within the plasmonic structure into the silicon, e.g., the semiconductor substrate, may be optimized. The plasmonic structure may be realized by different materials, which comprise a charge carrier density suitable for the case of application [11].

Following the functional principle of the internal photoemission, the buried metal-semiconductor junction (Schottky junction), or, e.g., the metal material-semiconductor junction, may carry great significance. The Schottky junction may form a barrier for the photo-generated electric charge carriers in the emission of metal or, e.g., metal material into the semiconductor. The properties of the interfaces may depend on the material pairing. Generally, e.g., metals, silicides, or metallic nitrides may be used on the “metal side” or, e.g., “metal material side”. For example, silicon, germanium, or corresponding alloys are possible as a semiconductor.

The structural sizes involved may be optimized for a particular wavelength range. Generally, the wavelength range of, e.g., 1 μm to about 12 μm, may be usefully addressed with embodiments of the present invention.

In addition to the geometry of the structures, the sensitivity of the proposed apparatuses, e.g., configured as Schottky photodiodes, may also be influenced or set by material selection. The charge carrier density of the metallic material or, e.g., the metal material, and the barrier height to the adjacent semiconductor may, in this regard, be significant influential variables. In addition, the semiconductor, i.e., for example, the semiconductor substrate, may have an n-(electrode) or p-(holes) doping and thus, the diode may be n- or p-conductive.

Furthermore, the plasmonic structure, that is, e.g., the lattice structure with metal material arranged at the trench floor, may be configured as a one-dimensional or two-dimensional lattice. In the case of one-dimensional lattices, the photodiode, e.g., as a configuration of an inventive apparatus, may become polarization-sensitive. This effect may be advantageously used for detecting polarization properties of electromagnetic radiation. In this case, the structures may be configured as elongate ridges. In the case of two-dimensional lattices, the polarization effect may get lost. This may be used, e.g., in a targeted manner, to manufacture polarization-independent components. Such lattices may be composed of, e.g., round, rectangular, or generally numerous basic structures. To this end, the arrangement of these basic structures to form lattices may take place in different ways. Thus, the lattice may comprise a square or hexagonal arrangement with various lattice constants.

Furthermore, an inventive apparatus, e.g., configured as a diode, may be composed of different substructures (lattices). Thus, for example, a combination of two one-dimensional lattices arranged vertical to one another (and next to one another) is possible. Here, it is to be noted that embodiments may also comprise any combination of basic structures and lattice arrangements.

A great advantage of embodiments of the present invention lies in the material selection, e.g., for the semiconductor substrate and the metal material, silicon (germanium)/metal (silicide). If the selection is suitable, e.g., regarding the specific application, it is possible to manufacture using the standard methods of silicon semiconductor technology or even have a CMOS compatibility. This entails an enormous cost advantage when producing large quantities. Particularly the comparison with the other detector materials common in this spectral range, e.g., NIR spectrum, may be favorable. Indium gallium arsenide (InGaAs) or mercury cadmium telluride (MCT) are, e.g., expensive materials which are additionally, like lead sulfide and lead selenide, pollutive. Thus, embodiments according to the present invention allow for great advantages regarding the material composition and manufacturing costs.

Based on FIGS. 2 and 3, further embodiments with optional features are to be discussed.

A further inventive embodiment 200 for an inventive component is based on a lattice structure 200 realized in silicon (see, as an example, FIG. 2). The lattice constant for this lattice can be between 100 and 1000 nm for a near-infrared component and up to 4000 nm for the mid-infrared range. The ridge height can be between 50 and 1000 nm or up to 4000 nm. A metal layer, e.g., as the metal material 230, can be deposited in the depression of the lattice. The volume above this metal layer can be filled with a material, e.g., as a filling structure 240, e.g., typically an insulator. The common or even, for example, planar surface can be covered with a continuous metal layer, which forms, for example, the reflector 250. The lattice structure of the silicon can be designed as a strip, an approximately polarization-independent component behavior can be shown in the realization as a perforated lattice structure (see FIG. 3b) as an example).

For the embodiment example explained above, FIG. 2 thus shows, for example, a schematic cross-section through the component, and FIG. 3 shows, for example, schematic top views at the level of the absorbing layer 230. In other words, FIGS. 2 and 3 additionally illustrate an inventive embodiment of a photodetector based on a plasmonic “perfect absorber” approach. FIG. 2 shows, for example, the cross-section through the component, FIG. 3a), for example, a top view of a polarization-dependent component, FIG. 3b), for example, shows a top view through a polarization-independent component.

### CONCLUSIONS AND FURTHER REMARKS

In the following, further embodiments of the invention are listed, and previously described embodiments are summarized in other words:
1. Photodetector for detecting electromagnetic radiation, including or consisting of
   a semiconductor substrate, which comprises a non-planar topography,
   a first electrically conductive layer,
   a second electrically conductive layer,
wherein the non-planar topography divides a surface of the semiconductor substrate in at least one higher and one lower area, and the first electrically conductive layer at least partially covers the lower area, and this results in a Schottky junction to the semiconductor, and wherein, by absorbing electromagnetic radiation, electrical charge carriers are emitted from the first conductive layer, via the Schottky junction and into the semiconductor substrate, and thereby, a photocurrent is generated, and wherein the first conductive layer is covered by a non-conductive material, which fills the lower areas, and wherein the second conductive layer covers at least a part of the higher and the covered lower areas jointly and serves as a reflector for the electromagnetic radiation.
2. Photodetector according to embodiment 1, wherein the semiconductor substrate consists of silicon or germanium, or of an alloy of silicon and germanium.
3. Photodetector according to one of the or the preceding embodiments, wherein the first conductive layer is a metal or a silicide or a metallic nitride.
4. Photodetector according to one of the or the preceding embodiments, wherein the semiconductor substrate is n-doped or p-doped.
5. Photodetector according to embodiment 4, wherein the doping is configured to be homogenous or gradual.
6. Photodetector according to one of the or the preceding embodiments, wherein structure sized of the lower area are selected such that the absorption of electromagnetic radiation in the first conductive layer is influenced by plasmonic effects.
7. Photodetector according to one of the or the preceding embodiments, wherein the first and the second conductive layers together act as a resonator for electromagnetic radiation.
8. Photodetector according to embodiments 6 and/or 7, wherein the absorption of electromagnetic radiation is increased by a cooperation of plasmonic and resonating effects.
9. Photodetector according to one or the preceding embodiments, wherein the wavelength of the electromagnetic radiation is between 1 μm and 3 μm.
10. Photodetector according to one or the preceding embodiments, wherein a wavelength of the electromagnetic radiation is up to 12 μm.
11. Photodetector according to one or the preceding embodiments, wherein the first electrically conductive layer is used for electrical contacting of the Schottky junction.
12. Photodetector according to one or the preceding embodiments, wherein the electromagnetic radiation is irradiated in from a rear side of the semiconductor substrate.
13. Photodetector according to one or the preceding embodiments, wherein the structures of the lower area and of the higher area form a periodic arrangement.
14. Photodetector according to embodiment 13, wherein the structures form a one-dimensional lattice.
15. Photodetector according to embodiment 13, wherein the structures form a two-dimensional lattice.
16. Photodetector according to embodiment 13, wherein the described structures have dimensions in height or extension of between 80 nm and 1200 nm.
17. Photodetector according to embodiment 13, wherein the described structures have dimensions in height or extension of up to 4000 nm.

All materials, environmental influences, electrical characteristics, and optical characteristics described herein are considered to be examples and are not exhaustive.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

[1] Casalino et.al., Opt. Express 20, 12599 (2012)
[2] B. Desiatov et al., “Plasmonic enhanced silicon pyramids for internal photoemission Schottky detectors in the near-infrared regime”, Optica, Jg. 2, no. 4, page 335, 2015, doi: 10.1364/OPTICA.b 2.000335.
[3] U.S. Pat. No. 5,285,098A
[4] Sebastian R. Borrello, “STRUCTURE AND METHOD INTERNAL PHOTOEMISSION,” US005285098A. U.S. Pat. No. 877,433, Feb. 8, 1994.
[5] B. Feng et al., “All-Si Photodetectors with a Resonant Cavity for Near-Infrared Polarimetric Detection” (eng), Nanoscale research letters, Jg. 14, no. 1, page 39, 2019, doi: 10.1186/s11671-019-2868-3.
[6] J. Duran und A. Sarangan, “Schottky-Barrier Photodiode Internal Quantum Efficiency Dependence on Nickel Silicide Film Thickness”, IEEE Photonics J., Jg. 11, no. 1, page 1-15, 2019, doi: 10.1109/JPHOT.2018.2886556.
[7] Edward P. Smith, Anne Itsuno, Justin Gordon Adams Wehner, “PHOTO-DETECTOR HAVING PLASMONIC RESONANCE AND PHOTON CRYSTAL THERMAL NOISE SUPPRESSION,” US20150221796A1. U.S. Ser. No. 14/174,172, Aug. 6, 2015.
[8] Z. Wang, X. Wang und J. Liu, “Nanophotonic hot-electron devices for infrared light detection,” WO 2019/018039 A2. US PCT/US2018/028688, Jan. 24, 2019.
[9] H.-L. Chen, K.-T. Lin, Y.-S. Lai und C.-C. Yu, “Photodetector and method of fabricating the same,” US 2015/0228837 A1. TW 14/616,890, Aug. 13, 2015.
[10] Z. Zhang, X. Han und K. He, “Perfect Absorber,” WO 2018/176270 A1. CN PCT/CN2017/078603, Oct. 4, 2018.
[11] JACEK GOSCINIAK, “WAVEGUIDE INTEGRATED PLASMONIC SCHOTTKY PHOTODETECTOR,” US2020/0144437A1. United States 16539,029, May 7, 2020.

1. An apparatus for absorbing electromagnetic radiation, the apparatus comprising:
a semiconductor substrate with a main side and a trench structure introduced into the main side and comprising at least one trench in the semiconductor substrate,
wherein each trench of the trench structure comprises a trench floor area, and
wherein the semiconductor substrate is transparent for the electromagnetic radiation; and
a metal material arranged in the trench floor area,
wherein, together with the semiconductor substrate, the metal material provides a Schottky junction configured for absorbing the electromagnetic radiation; and
a filling structure arranged in the trench and filling the trench and forming a common surface with the main side; and
a reflector arranged at the common surface and configured to at least partially reflect the electromagnetic radiation received by the semiconductor substrate in the direction of the metal material.

2. The apparatus according to claim 1,
wherein the trench structure comprises a multitude of trenches; and
wherein the metal material is arranged in each trench floor area of the multitude of trenches; and
wherein, together with the material arranged in each trench floor area of the multitude of trenches, the trench structure forms a lattice structure; and
wherein the lattice structure is configured to at least partially transmit electromagnetic radiation in a predetermined wavelength range and to at least partially reflect electromagnetic radiation outside of the predetermined wavelength range.

3. The apparatus according to claim 2, wherein the lattice structure comprises a lattice constant, and wherein the lattice constant is determined by the distance of the metal material of two adjacent trenches of the trench structure; and
wherein the lattice constant is at least 100 nm and at most 1000 nm, or
wherein the lattice constant is at least 100 nm and at most 4000 nm.

4. The apparatus according to claim 2,
wherein the lattice structure is configured to transmit the electromagnetic radiation in dependence on the polarization of the electromagnetic radiation.

5. The apparatus according to claim 4,
wherein the lattice structure is a one-dimensional lattice structure and causes a transmission of the electromagnetic radiation in dependence on the polarization of the electromagnetic radiation.

6. The apparatus according to claim 4,
wherein the trenches of the trench structure comprise, in a plane parallel to the main side of the semiconductor substrate, a first extension and a second extension approximately perpendicular to the first extension, wherein the first extension is greater than the second extension, and
wherein the trenches of the trench structure are arranged on the main side in parallel to one another with an approximately equal distance in each instance.

7. The apparatus according to claim 2,
wherein the lattice structure is configured to transmit the electromagnetic radiation with a first polarization direction and a second polarization direction.

8. The apparatus according to claim 7,
wherein the trenches of the trench structure are connected to one another and formed as a trench surface, and
wherein the semiconductor substrate comprises columns in the area of the trench structure, wherein the columns are arranged with a predetermined distance from one another in a regular arrangement.

9. The apparatus according to claim 2,
wherein the apparatus comprises a multitude of different lattice structures.

10. The apparatus according to claim 9,
wherein the different lattice structures are arranged irregularly and/or distributed randomly.

11. The apparatus according to claim 1,
wherein the metal material arranged in the trench floor area is configured to facilitate the absorption of the electromagnetic radiation at the Schottky junction by means of plasmonic effects.

12. The apparatus according to claim 1,
wherein the Schottky junction is adapted to a wavelength range; and
wherein the metal material is dimensioned, in dependence on the wavelength range, such that, upon irradiation of the apparatus with electromagnetic radiation with wavelengths within the wavelength range, plasmonic effects occur or are amplified, in order to facilitate the absorption of the electromagnetic radiation at the Schottky junction by means of the plasmonic effects, and/or
wherein the metal material is composed, in dependence on the wavelength range, such that, upon irradiation of the apparatus with electromagnetic radiation with wavelengths within the wavelength range, the absorption is facilitated by the composition of the metal material.

13. The apparatus according to claim 1,
wherein the metal material is configured to form, together with the reflector, a resonator for the electromagnetic radiation.

14. The apparatus according to claim 1,
wherein the apparatus is configured to absorb the electromagnetic radiation based on an internal photoemission by using the Schottky junction,
wherein the absorption of the electromagnetic radiation is facilitated by plasmonic effects in the metal material and by multi-reflections between the reflector and the metal material.

15. The apparatus according to claim 1, wherein the apparatus comprises a first and second electric contacting, and
wherein the first contacting is connected in an electrical conductive way to the metal material; and
wherein the second contacting is connected in an electrically conductive way to the semiconductor substrate; and
wherein the first and second contacting are configured to provide a photocurrent, on the basis of an internal photoemission, through electromagnetic radiation absorbed at the Schottky junction.

16. The apparatus according to claim 15, wherein the first and second contactings are arranged at opposite sides of the apparatus; or
wherein the first and second contactings are arranged on a same side of the apparatus.

17. The apparatus according to claim 1,
wherein the apparatus is configured to absorb electromagnetic radiation with a wavelength of
at least 1 μm and at most 12 μm, or
at least 1 μm and at most 3 μm.

18. The apparatus according to claim 1,
wherein the semiconductor substrate comprises a doping, and wherein a doping degree of the doping towards the Schottky junction is constant, stepped, or gradually variable.

19. The apparatus according to claim 1,
wherein the semiconductor substrate comprises a layer stack; and/or
wherein the semiconductor substrate comprises silicon, germanium, and/or a material compound comprising silicon and/or germanium; and/or
wherein the metal material comprises a layer stack; and/or
wherein the metal material comprises a metal, a silicide, and/or a metallic nitride; and/or
wherein the filling material comprises a semiconductor material and/or an insulator material.

20. The apparatus according to claim 1, wherein the metal material comprises at least one of aluminum, copper, nickel, gold, titanium, nickel silicide, cobalt silicide, titanium silicide, and/or titanium nitride.

21. The apparatus according to claim 1, wherein the filling material comprises Poly-Si, SiO₂, and/or SiN.

22. The apparatus according to claim 1,
wherein the trench structure comprises an extension vertical to the main side of the semiconductor substrate, which is at least 50 nm and at most 1000 nm, or at least 80 nm and at most 1200 nm, or at least 50 nm and at most 4000 nm.

23. A system for use in an image sensor, comprising:
a multitude of apparatuses according to claim 1, wherein the multitude of apparatuses is arranged in a grid or in a matrix, and
wherein one or multiple apparatuses of the multitude of apparatuses are each assigned to each grid or matrix element, and
wherein the system is configured to evaluate the one or multiple apparatuses of a grid or matrix element, each regarding a photocurrent created by absorption of electromagnetic radiation.

24. A method for absorbing electromagnetic radiation, comprising:
irradiating a semiconductor substrate with the electromagnetic radiation,
wherein the semiconductor substrate is irradiated from a rear side opposite a main side of the semiconductor substrate, and
wherein the semiconductor substrate comprises a trench structure introduced into the main side of the semiconductor substrate and comprising at least one trench in the semiconductor substrate, wherein each trench of the trench structure comprises a trench floor area, and
wherein the semiconductor substrate is transparent for the electromagnetic radiation, and
wherein a metal material is arranged in the trench floor area, wherein, together with the semiconductor substrate, the metal material provides a Schottky junction configured for absorbing the electromagnetic radiation, and
wherein a filling structure is arranged in the trench and filling the trench and forms, together with the main side, a common surface
absorbing the electromagnetic radiation in the Schottky junction; and/or
at least partially transmitting the electromagnetic radiation through the trench structure, and at least partially reflecting the electromagnetic radiation at a reflector arranged at the common surface and configured to reflect the electromagnetic radiation received by the semiconductor substrate in the direction of the metal material.

25. A method for manufacturing an apparatus for absorbing electromagnetic radiation, the method comprising:
providing a semiconductor substrate with a main side, wherein the semiconductor substrate is transparent for the electromagnetic radiation; and
introducing a trench structure into the main side of the semiconductor substrate and comprising at least one trench in the semiconductor substrate, and wherein each trench of the trench structure comprises a trench floor area; and
arranging a metal material in the trench floor area, wherein, together with the semiconductor substrate, the metal material provides a Schottky junction configured for absorbing the electromagnetic radiation; and
filling the trench with a filling structure, so that, together with the main side, the filling structure forms a common surface; and
arranging a reflector at the common surface, wherein the reflector is configured to at least partially reflect the electromagnetic radiation received by the semiconductor substrate in the direction of the metal material.
